(19) United States
(12) Patent Application Publication
(10) Pub. No.: US 2014/0261663 A1
(43) Pub. Date: Sep. 18, 2014

(54) High Haze Underlayer For Solar Cell

(71) Applicant: PPG Industries Ohio, Inc., Cleveland, OH (US)

(72) Inventors: James W. McCamy, Export, PA (US); Peter Tausch, Decatur, IL (US); Gary J. Nelis, Pittsburgh, PA (US); Songwei Lu, Wexford, PA (US)

(73) Assignee: PPG Industries Ohio, Inc., Cleveland, OH (US)

(21) Appl. No.: 14/199,131

(22) Filed: Mar. 6, 2014

Related U.S. Application Data
(60) Provisional application No. 61/777,182, filed on Mar. 12, 2013.

(51) Int. Cl. H01L 31/0216

(52) U.S. Cl. CPC H01L 31/02168
USPC 136/256; 428/142

(57) ABSTRACT

A solar cell has a substrate and an undercoating formed over at least a portion of the substrate. The undercoating includes a continuous first layer of tin oxide and a second layer having oxides of Sn, P, and Si. A transparent conductive coating is formed over at least a portion of the undercoating. The second layer includes protrusions on an upper surface that cause uneven crystal growth of the conductive coating.

### CROSS REFERENCE TO RELATED APPLICATION

This application claims priority to U.S. Provisional Application No. 61/777,182, filed Mar. 12, 2013, herein incorporated by reference in its entirety.

### BACKGROUND OF THE INVENTION

1. Field of the Invention

This invention relates generally to solar cells and, in one particular embodiment, to an amorphous silicon thin film solar cell having an improved underlayer structure.

2. Technical Considerations

A conventional amorphous silicon thin film solar cell typically includes a glass substrate over which is provided a transparent conductive oxide (TCO) contact layer and an amorphous silicon thin film active layer having a p-n junction. A rear metallic layer acts as a reflector and back contact. The TCO has an irregular surface to increase light scattering. In solar cells, light scattering or “haze” is used to trap light in the active region of the cell. The more light that is trapped in the cell, the higher the efficiency that can be obtained. However, the haze cannot be so great as to adversely impact upon the transparency of light through the TCO. Therefore, light trapping is an important issue when trying to improve the efficiency of solar cells and is particularly important in thin film cell design. However, with thin film devices, this light trapping is more difficult because the layer thicknesses are much thinner than those in previously know monocrystalline devices. As the film thicknesses are reduced, they tend toward coatings having predominantly parallel surfaces. Such parallel surfaces typically do not provide significant light scattering.

Another important feature for thin film solar cells is surface resistivity of the TCO. When the cell is irradiated, electrons generated by the irradiation move through the silicon and into the transparent conductive oxide layer. It is important for photoelectric conversion efficiency that the electrons move as rapidly as possible through the conductive layer. That is, it is desirable if the surface resistivity of the transparent conductive layer is low. It is also desirable if the transparent conductive layer is highly transparent to permit the maximum amount of solar radiation to pass to the silicon layer.

Therefore, it would be desirable to provide a coating configuration for a solar cell that enhances electron flow through the transparent conductive oxide layer, while also enhancing the light scattering and transparency characteristics of the solar cell.

### SUMMARY OF THE INVENTION

A silicon thin film solar cell comprises a substrate and an undercoating formed over at least a portion of the substrate. The undercoating comprises a continuous first layer comprising tin oxide; and a second layer comprising oxides of at least two of Sn, P, and Si. A conductive coating is formed over at least a portion of the first coating, wherein the conductive coating comprises oxides of one or more of Zn, Fe, Mn, Al, Ce, Sn, Sb, Hf, Zr, Ni, Zn, Bi, Ti, Co, Cr, Si or In, or an alloy of two or more of these materials. In a preferred embodiment, the first layer consists of a continuous layer of undoped tin oxide.

In one particular solar cell, the substrate is glass, the first layer comprises a continuous tin oxide layer having a thickness in the range of 10 nm to 25 nm. The second layer comprises a mixture of silica, tin oxide, and phosphorous oxide having a thickness in the range of 10 nm to 40 nm and having tin oxide in the range of 1 mole % to 40 mole %, such as less than 20 mole %. The conductive coating comprises fluorine doped tin oxide having a thickness greater than 470 nm.

A solar cell has a substrate and an undercoating formed over at least a portion of the substrate. The undercoating includes a continuous first layer of tin oxide and a second layer having oxides of Sn, P, and Si. A transparent conductive coating is formed over at least a portion of the undercoating. The second layer includes protrusions on an upper surface that cause uneven crystal growth of the conductive coating.

A coated article comprises a glass substrate and an undercoating formed over at least a portion of the substrate. The undercoating comprises a continuous first layer comprising tin oxide having a thickness in the range of 10 nm to 25 nm and a second layer comprising oxides of Sn, P, and Si. The second layer comprises 50 to 60 atomic percent silicon, 12 to 16 atomic percent tin, and 25 to 30 atomic percent phosphorous. A transparent conductive coating comprising fluorine doped tin oxide is formed over at least a portion of the undercoating. The second layer includes protrusions on an upper surface that cause uneven crystal growth of the conductive coating.

### BRIEF DESCRIPTION OF THE DRAWINGS

A complete understanding of the invention will be obtained from the following description when taken in connection with the accompanying drawing figures.

FIG. 1 is a side, sectional view (not to scale) of a solar cell substrate incorporating an undercoating of the invention; and

FIG. 2 is a side view (not to scale) of a solar cell substrate having an undercoating of the invention.

### DESCRIPTION OF THE PREFERRED EMBODIMENTS

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. Further, as used herein, the terms “formed over”, “deposited over”, or “provided over” mean formed, deposited, or provided on but not necessarily in direct contact with the surface. For example, a coating layer “formed over” a substrate does not preclude the presence of one or more other coating layers or films of the same or different composition located between the formed coating layer and the substrate. As used herein, the terms “polymer” or “polymeric” include oligomers, homopolymers, copolymers, and terpolymers, e.g., polymers formed from two or more types of monomers or polymers. The terms “visible region” or “visible light” refer to electromagnetic radiation having a wavelength in the range of 380 nm to 760 nm. The terms “infrared region” or “infrared radiation” refer to electromagnetic radiation having a wavelength in the range of greater than 760 nm to 100,000 nm. The terms “ultraviolet region” or “ultraviolet radiation” mean electromagnetic energy having a wavelength in the range of 200 nm to less than 380 nm. The terms “microwave region” or “microwave radiation” refer to electromagnetic radiation having a frequency in the range of 300 megahertz to 300 gigahertz. Additionally, all documents, such as, but not limited to, issued patents and patent applications, referred to herein are to be considered to be “incorporated by reference” in their entirety. In the following discussion, the refractive index values are those for a reference wavelength of 550 nanometers (nm). The term “film” refers to a region of a coating having a desired or selected composition. A “layer” comprises one or more “films”. A “coating” or “coating stack” is comprised of one or more “layers”. The term “continuous layer” means that the coating material is applied to cover the underlying layer or substrate and that no bare areas are intentionally formed. By “undoped” is meant that no dopants are intentionally added to the coating material.

An exemplary solar cell 10 incorporating features of the invention is shown in FIG. 1. The solar cell 10 includes a substrate 12 having at least one major surface 14. An undercoating 16 of the invention is formed over at least a portion of the major surface 14. The undercoating 16 has a first layer 18 and a second layer 20. A transparent conductive oxide (TCO) coating 22 is formed over at least a portion of the undercoating 16. A layer of amorphous silicon 24 is formed over at least a portion of the TCO coating 22. A metal or metal-containing layer 26 is formed over at least a portion of the amorphous silicon layer 24.

In the broad practice of the invention, the substrate 12 can include any desired material having any desired characteristics. For example, the substrate can be transparent or translucent to visible light. By “transparent” is meant having a visible light transmittance of greater than 0% up to 100%. Alternatively, the substrate 12 can be translucent. By “translucent” is meant allowing electromagnetic energy (e.g., visible light) to pass through but diffusing this energy such that objects on the side opposite the viewer are not clearly visible. Examples of suitable materials include, but are not limited to, plastic substrates (such as acrylic polymers, such as polyacrylates; polyalkylmethacrylates, such as polymethylmethacrylates, polyethylmethacrylates, polypropylmethacrylates, and the like; polyurethanes; polycarbonates; polyalkylterephthalates, such as polyethyleneterephthalate (PET), polypropyleneterephthalates, polybutyleneterephthalates, and the like; polysiloxane-containing polymers; or copolymers of any monomers for preparing these, or any mixtures thereof); glass substrates; or mixtures or combinations of any of the above. For example, the substrate 12 can include conventional soda-lime-silicate glass, borosilicate glass, or leaded glass. The glass can be clear glass. By “clear glass” is meant non-tinted or non-colored glass. Alternatively, the glass can be tinted or otherwise colored glass. The glass can be annealed or heat-treated glass. As used herein, the term “heat treated” means tempered or at least partially tempered. The glass can be of any type, such as conventional float glass, and can be of any composition having any optical properties, e.g., any value of visible transmission, ultraviolet transmission, infrared transmission, and/or total solar energy transmission. By “float glass” is meant glass formed by a conventional float process in which molten glass is deposited onto a molten metal bath and controllably cooled to form a float glass ribbon. Non-limiting examples of glass that can be used for the practice of the invention include Solargreen®, Solextra®, GL-20®, GL-35™, Solarbronze®, Starphire®, Solarphire®, Solarphire PV® and Solargray® glass, all commercially available from PPG Industries Inc. of Pittsburgh, Pa.

The substrate 12 can be of any desired dimensions, e.g., length, width, shape, or thickness. For example, the substrate 12 can be planar, curved, or have both planar and curved portions. In one non-limiting embodiment, the substrate 12 can have a thickness in the range of 0.5 mm to 10 mm, such as 1 mm to 5 mm, such as 2 mm to 4 mm, such as 3 mm to 4 mm.

The substrate 12 can have a high visible light transmission at a reference wavelength of 550 nanometers (nm). By “high visible light transmission” is meant visible light transmission at 550 nm of greater than or equal to 85%, such as greater than or equal to 87%, such as greater than or equal to 90%, such as greater than or equal to 91%, such as greater than or equal to 92%.

In the practice of the invention, the undercoating 16 is a multilayer coating having two or more coating layers. The first layer 18 can provide a barrier between the substrate 12 and the overlying coating layers. The first layer 18 is a continuous layer having a thickness of less than 50 nm, such as less than 40 nm, such as less than 30 nm, such as less than 25 nm, such as less than 20 nm, such as less than 15 nm, such as in the range of 5 nm to 25 nm, such as in the range of 5 nm to 15 nm.

The first layer 18 is preferably an undoped metal oxide layer. In a preferred embodiment, the first layer 18 comprises a continuous layer of undoped tin oxide.

The second layer 20 comprises oxides of tin, silicon, and phosphorus. The oxides can be present in any desired proportions. The relative proportions of the oxides can be present in any desired amount, such as 0.1 wt. % to 99.9 wt. % of tin oxide, 99.9 wt. % to 0.1 wt. % silica, and 0.1 wt. % to 99.9 wt. % phosphorous oxide. One exemplary second layer 20 comprises oxides of tin, silicon, and phosphorous with the tin present in the range of 5 atomic percent to 30 atomic percent, such as 10 atomic percent to 20 atomic percent, such as 10 atomic percent to 15 atomic percent, such as 12 atomic percent to 15 atomic percent, such as 14 atomic percent to 15 atomic percent, such as 14.5 atomic percent. The silicon is present in the range of 40 atomic percent to 70 atomic percent, such as 45 atomic percent to 70 atomic percent, such as 45 atomic percent to 65 atomic percent, such as 50 atomic percent to 65 atomic percent, such as 50 atomic percent to 60 atomic percent, such as 55 atomic percent to 60 atomic percent, such as 57 atomic percent. The phosphorous is present in the range of 15 atomic percent to 40 atomic percent, such as 20 atomic percent to 35 atomic percent, such as 20 atomic percent to 30 atomic percent, such as 25 atomic percent to 30 atomic percent, such as 28.5 atomic percent.

The second layer 20 can have any desired thickness, such as but not limited to, 10 nm to 100 nm, such as 10 nm to 80 nm, such as 10 nm to 60 nm, such as 10 nm to 40 nm, such as 20 nm to 40 nm, such as 20 nm to 35 nm, such as 20 nm to 30 nm, such as 25 nm. For example, the second layer 20 can have a thickness less than 40 nm, such as less than 37 nm, such as less than 35 nm, such as less than 30 nm.

The second layer 20 can include (as determined by x-ray fluorescence), [Sn] in the range of 1 μg/cm² to 2 μg/cm², such 1.2 to 2 μg/cm², such as 1.5 to 2 μg/cm², such as 1.8 μg/cm². The second layer can include (again, by XRF) [P] in the range of 2 μg/cm² to 2.5 μg/cm², such 2.1 to 2.5 μg/cm², such as 2.2 to 2.4 μg/cm², such as 2.31 μg/cm².

The TCO layer 22 comprises at least one conductive oxide layer, such as a doped oxide layer. For example, the TCO layer 22 can include one or more oxide materials, such as but not limited to, one or more oxides of one or more of Zn, Fe, Mn, Al, Ce, Sn, Sb, Hf, Zr, Ni, Zn, Bi, Ti, Co, Cr, Si or In or an alloy of two or more of these materials, such as zinc stannate. The TCO layer 22 can also include one or more dopant materials, such as but not limited to, F, In, Al, P, and/or Sb. In one non-limiting embodiment, the TCO layer 22 is a fluorine doped tin oxide coating, with the fluorine present in an amount less than 20 wt. % based on the total weight of the coating, such as less than 15 wt. %, such as less than 13 wt. %, such as less than 10 wt. %, such as less than 5 wt. %, such as less than 4 wt. %, such as less than 2 wt. %, such as less than 1 wt. %. The TCO layer 22 can be amorphous, crystalline or at least partly crystalline.

The TCO layer 22 can have a thickness greater than 200 nm, such as greater than 250 nm, such as greater than 350 nm, such as greater than 380 nm, such as greater than 400 nm, such as greater than 420 nm, such as greater than 470 nm, such as greater than 500 nm, such as greater than 600 nm. In one non-limiting embodiment, the TCO layer 22 comprises fluorine doped tin oxide and has a thickness as described above, such as in the range of 350 nm to 1,000 nm, such as 400 nm to 800 nm, such as 500 nm to 700 nm, such as 600 nm to 700 nm, such as 650 nm.

The TCO layer 22 can have a sheet resistance of less than 15 ohms per square (Ω/□), such as less than 14Ω/□, such as less than 13.5Ω/□, such as less than 13Ω/□, such as less than 12Ω/□, such as less than 11Ω/□, such as less than 10Ω/□.

The TCO layer 22 can have a surface roughness (RMS) in the range of 5 nm to 60 nm, such as 5 nm to 40 nm, such as 5 nm to 30 nm, such as 10 nm to 30 nm, such as 10 nm to 20 nm, such as 10 nm to 15 nm, such as 11 nm to 15 nm. The surface roughness of the underlayer 16 will be less than the surface roughness of the TCO layer 22.

The amorphous silicon layer 24 can have a thickness in the range of 200 nm to 1,000 nm, such as 200 nm to 800 nm, such as 300 nm to 500 nm, such as 300 nm to 400 nm, such as 350 nm.

The metal containing layer 26 can be metallic or can include one or more metal oxide materials. Examples of suitable metal oxide materials include, but are not limited to, oxides of one or more of Zn, Fe, Mn, Al, Ce, Sn, Sb, Hf, Zr, Ni, Zn, Bi, Ti, Co, Cr, Si or In or an alloy of two or more of these materials, such as zinc stannate. The metal containing layer 26 can have a thickness in the range of 50 nm to 500 nm, such as 50 nm to 300 nm, such as 50 nm to 200 nm, such as 100 nm to 200 nm, such as 150 nm.

The coating layers, e.g., the undercoating 16, TCO layer 22, amorphous silicon layer 24, and the metal layer 26 can be formed over at least a portion of the substrate 12 by any conventional method, such as but not limited to, spray pyrolysis, chemical vapor deposition (CVD), or magnetron sputtered vacuum deposition (MSVD). The layers can all be formed by the same method or different layers can be formed by different methods. In the spray pyrolysis method, an organic or metal-containing precursor composition having one or more oxide precursor materials, e.g., precursor materials for titania and/or silica and/or alumina and/or phosphorous oxide and/or zirconia, is carried in a suspension, e.g., an aqueous or non-aqueous solution, and is directed toward the surface of the substrate while the substrate is at a temperature high enough to cause the precursor composition to decompose and form a coating on the substrate. The composition can include one or more dopant materials. However, in a preferred embodiment, the composition for the first layer of the underlayer does not intentionally include dopants. In a CVD method, a precursor composition is carried in a carrier gas, e.g., nitrogen gas, and is directed toward the heated substrate. In the MSVD method, one or more metal-containing cathode targets are sputtered under reduced pressure in an inert or oxygen-containing atmosphere to deposit a sputter coating over substrate. The substrate can be heated during or after coating to cause crystallization of the sputtered coating to form the coating.

In one non-limiting practice of the invention, one or more CVD coating apparatus can be employed at one or more positions in a conventional float glass ribbon manufacturing process. For example, CVD coating apparatus may be employed as the float glass ribbon travels through the tin bath, after it exits the tin bath, before it enters the annealing lehr, as it travels through the annealing lehr, or after it exits the annealing lehr. Because the CVD method can coat a moving float glass ribbon, yet withstand the harsh environments associated with manufacturing the float glass ribbon, the CVD method is particularly well suited to deposit coatings on the float glass ribbon in the molten tin bath.

In one non-limiting embodiment, one or more CVD coaters can be located in the tin bath above the molten tin pool. As the float glass ribbon moves through the tin bath, the vaporized precursor composition can be added to a carrier gas and directed onto the top surface of the ribbon. The precursor composition decomposes to form a coating on the ribbon. The coating composition can be deposited on the ribbon at a location in which the temperature of the ribbon is less than 1300° F. (704° C.), such as less than 1250° F. (677° C.), such as less than 1200° F. (649° C.), such as less than 1190° F. (643° C.), such as less than 1150° F. (621° C.), such as less than 1130° F. (610° C.), such as in the range of 1190° F. to 1200° F. (643° C. to 649° C.). This is particularly useful in depositing a TCO layer 22 (e.g., fluorine doped tin oxide) having reduced surface resistivity since the lower the deposition temperature, the lower will be the resultant surface resistivity.

One non-limiting example of a silica precursor is tetraethylorthosilicate (TEOS). Examples of phosphorous oxide precursors include, but are not limited to, triethyl phosphite and triethyl phosphate. Examples of a tin oxide precursor include monobutyltintrichloride (MBTC).

A coated substrate 12 incorporating features of the invention is shown in FIG. 2. The substrate 12 is as described above. A continuous first layer 18 of tin oxide is formed over at least a portion of the major surface 14 of the substrate 12. A second layer 20 of tin oxide, silicon oxide, and phosphorous oxide is formed over at least a portion of the first layer 18. It has been discovered that under certain coating conditions, protrusions 30 are formed on the upper surface of the second layer 20. For example, these protrusions 30 can be formed when the second layer 20 is less than 40 nm thick, such as less than 39 nm, such as less than 38 nm, such as less than 37 nm, such as less than 35 nm, such as less than 30 nm thick and/or has a tin oxide composition of less than 30 weight percent, such as less than 25 weight percent, such as less than 20 weight percent, such as less than 15 weight percent. These protrusions 30 appear to be rich in phosphorous and provide nucleation cites for uneven crystal growth of the conductive oxide 22. In FIG. 2, crystals 32 of the conductive oxide layer 22 are shown schematically (not to scale). Over the relatively flat upper surface of the second layer 20, the crystals 32 are generally uniform in direction, i.e. extend upwardly and generally perpendicular to the flat portion of the upper surface of the second layer 20. However, over the non-flat, e.g. curved, surface of the protrusion 30, the crystal orientation is more random, i.e. less uniform, which causes increased haze.

It will be readily appreciated by those skilled in the art that modifications may be made to the invention without departing from the concepts disclosed in the foregoing description. Accordingly, the particular embodiments described in detail herein are illustrative only and are not limiting to the scope of the invention, which is to be given the full breadth of the appended claims and any and all equivalents thereof.

The invention claimed is:

1. A solar cell, comprising:
a substrate;
an undercoating formed over at least a portion of the substrate, the undercoating comprising:
a continuous first layer comprising tin oxide; and
a second layer comprising oxides of Sn, P, and Si; and
a transparent conductive coating formed over at least a portion of the undercoating, wherein the second layer includes protrusions on an upper surface that cause uneven crystal growth of the conductive coating.

2. The solar cell of claim 1, wherein the substrate is glass.

3. The solar cell of claim 1, wherein the first layer consists of a continuous layer of undoped tin oxide.

4. The solar cell of claim 1, wherein the first layer has a thickness in the range of 10 nm to 25 nm.

5. The solar cell of claim 1, wherein the second layer comprises 50 to 60 atomic percent silicon, 12 to 16 atomic percent tin, and 25 to 30 atomic percent phosphorous.

6. The solar cell of claim 1, wherein the second layer has a thickness less than 40 nm.

7. The solar cell of claim 1, wherein the transparent conductive coating comprises fluorine doped tin oxide.

8. The solar cell of claim 1, wherein the substrate is glass, the first layer comprises a continuous layer of undoped tin oxide having a thickness in the range of 10 nm to 25 nm, the second layer comprises a mixture of silica, tin oxide, and phosphorous oxide having a thickness less than or equal to 37 nm, and wherein the second layer includes less than or equal to 20 weight percent tin oxide.

9. The solar cell of claim 1, wherein the transparent conductive coating has a thickness in the range of 500 nm to 700 nm.

10. The solar cell of claim 1, wherein the transparent conductive coating has a sheet resistance of less than 10Ω/□.

11. The solar cell of claim 1, wherein the transparent conductive coating has a surface roughness in the range of 10 nm to 15 nm.

12. The solar cell of claim 1, wherein the underlayer has a surface roughness less than the surface roughness of the transparent conductive coating.

13. The solar cell of claim 3, wherein the first layer has a thickness in the range of 10 nm to 25 nm.

14. The solar cell of claim 13, wherein the second layer comprises 50 to 60 atomic percent silicon, 12 to 16 atomic percent tin, and 25 to 30 atomic percent phosphorous.

15. The solar cell of claim 14, wherein the second layer has a thickness less than 40 nm.

16. The solar cell of claim 15, wherein the transparent conductive coating comprises fluorine doped tin oxide.

17. The solar cell of claim 3, wherein the substrate is glass, the first layer comprises a continuous layer of undoped tin oxide having a thickness in the range of 10 nm to 25 nm, the second layer comprises a mixture of silica, tin oxide, and phosphorous oxide having a thickness less than or equal to 37 nm, and wherein the second layer includes less than or equal to 20 weight percent tin oxide.

18. The solar cell of claim 16, wherein the transparent conductive coating has a thickness in the range of 500 nm to 700 nm and a sheet resistance of less than 10Ω/□.

19. The solar cell of claim 18, wherein the underlayer has a surface roughness less than the surface roughness of the transparent conductive coating.

20. A coated article, comprising:
a glass substrate;
an undercoating formed over at least a portion of the substrate, the undercoating comprising:
a continuous first layer consisting of undoped tin oxide having a thickness in the range of 10 nm to 25 nm; and
a second layer comprising oxides of Sn, P, and Si, wherein the second layer comprises 50 to 60 atomic percent silicon, 12 to 16 atomic percent tin, and 25 to 30 atomic percent phosphorous; and
a transparent conductive coating comprising fluorine doped tin oxide formed over at least a portion of the undercoating, wherein the second layer includes protrusions on an upper surface that cause uneven crystal growth of the conductive coating.
